(19) United States
(12) Patent Application Publication
(10) Pub. No.: US 2023/0107063 A1
(43) Pub. Date: Apr. 6, 2023

(54) DISPLAY PANEL AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventors: Xuebin Yao, Shenzhen (CN); Bangyin Peng, Shenzhen (CN); Ilgon Kim, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/971,281

(22) PCT Filed: Jul. 13, 2020
(86) PCT No.: PCT/CN2020/101633

§ 371 Date: Aug. 19, 2020

(30) Foreign Application Priority Data
Jun. 8, 2020 (CN) 202010512595.4

(51) Int. Cl. G02F 1/1362; G02F 1/1343; G02F 1/1335; H01L 27/12

(52) U.S. Cl. CPC G02F 1/136209; G02F 1/133514; G02F 1/134345; G02F 1/136286; H01L 27/124; G02F 1/133345; G02F 1/136222

(57) ABSTRACT

A display panel and a display device are provided. The display panel includes an array substrate including a plurality of scan lines, a plurality of data lines, and a first common electrode, wherein the plurality of scan lines and the plurality of data lines are intersected to form a plurality of sub-pixel regions. The first common electrode includes a corner portion positioned within its corresponding sub-pixel region. The display panel includes a light-shielding portion that covers the corner portion, and the corner portion is shielded by providing the light-shielding portion.

### FIELD OF INVENTION

The present application relates to the technical field of display panels, in particular to a display panel and a display device.

### BACKGROUND OF INVENTION

In a field of current display technology, liquid crystal displays (LCDs) have many advantages such as thinness, power saving, free of radiation, etc., and thus have been widely used. For example, LCD televisions (TVs), mobile phones, personal digital assistants (PDAs), digital cameras, computer screens or laptop screens, etc., dominate a field of flat panel displays.

Current LCD TV products mainly adopt vertical alignment (VA) type liquid crystal display panel technology. As shown in FIG. 1, a VA type liquid crystal display panel includes a scan line 21; a data line 41; a common electrode 22 (Acorn, described as first common electrode in this application) on an array substrate side; a plurality of sub-pixels 101 formed by crossing a plurality of scan lines 21 and a plurality of data lines 41, wherein a black matrix 71 covers a portion of the common electrode 22 (Acorn, first common electrode) on the array substrate side extending in a first direction (horizontal direction in FIG. 1) and the scan line 21. A function of the common electrode (Acorn, first common electrode) on the array substrate side is to: (1) realize different voltages between the sub-pixels in a main region and the sub-pixels in a sub-region to achieve an eight-domain display effect, and (2) form a storage capacitor with a pixel electrode to maintain display for one frame time. In a current ultra-high definition (8K) display panel, when designing the common electrode on a side of the array substrate, metal corners (within the dotted circle in FIG. 1) will be designed as right angles. However, due to capability limitation of exposure equipment, corners of the common electrode (Acorn, first common electrode) on the array substrate side cannot be fully exposed in an actual process, and the metal corners of the common electrode on the array substrate side will be exposed to an approximate shape of a circular arc, polygon, or triangle. For example, a corner portion 220 of the common electrode 22 on the array substrate side shown in FIG. 1 (within the dotted frame). Light reflection and light leakage are prone to occur at the corner portion 220 when the display panel is in a dark state, thereby causing a decrease in contrast of the display panel and affecting user’s viewing experience. Especially for the ultra-high definition (8K) display panels, because there are greater number of pixels in the display panel, light leakage at the corner portions 220 will increase, resulting in a more serious decrease in the contrast of the display panel.

Therefore, it is urgent to develop a display panel to solve the above technical problems.

### TECHNICAL PROBLEM

Embodiments of the present application provide a display panel and a display device to solve the problems of brightness increase and contrast decrease in a dark state caused by light reflection from a corner portion of a first common electrode in a conventional display panel.

### SUMMARY OF INVENTION

A display panel, including: an array substrate including a plurality of scan lines, a plurality of data lines, and a first common electrode, wherein the plurality of scan lines and the plurality of data lines are intersected to form a plurality of sub-pixel regions, the first common electrode includes a corner portion positioned within a corresponding sub-pixel region; and a light-shielding portion covering the corner portion.

The present application also proposes a display device including a backlight module and a display panel on the backlight module. The display panel includes: an array substrate including a plurality of scan lines, a plurality of data lines, and a first common electrode, wherein the plurality of scan lines and the plurality of data lines are intersected to form a plurality of sub-pixel regions, the first common electrode includes a corner portion positioned within a corresponding sub-pixel region; and a light-shielding portion covering the corner portion.

### BENEFICIAL EFFECT

The beneficial effects of the present application are achieved by providing a light-shielding portion at a position corresponding to a corner portion of the first common electrode. The corner portion covered with the light-shielding portion relieves the problem of brightness increase in a dark state caused by light reflection from the corner portion of the first common electrode, improves the contrast of the display panel, and improves the display quality.

### DESCRIPTION OF DRAWINGS

FIG. 1 is a schematic top view of a partial structure of a display panel provided by the prior art.

FIG. 2 is a schematic top view of a partial structure of a display panel provided in embodiment 1 of the present application.

FIG. 3 is a schematic top view of a first-shaped light-shielding portion of the display panel provided in embodiment 1 of the present application.

FIG. 4 is a schematic top view of a second-shaped light-shielding portion of the display panel provided in embodiment 1 of the present application.

FIG. 5 is a schematic top view of a partial structure of a display panel provided by embodiment 2 of the present application.

FIG. 6 is a schematic top view of a light-shielding portion of the display panel provided in embodiment 2 of the present application.

FIG. 7 is a schematic structural diagram of an AA cross-section of a light-shielding portion of a display panel provided in embodiment 3 of the present application.

FIG. 8 is a schematic structural diagram of an AA cross-section of a light-shielding portion of a display panel according to embodiment 4 of the present application.

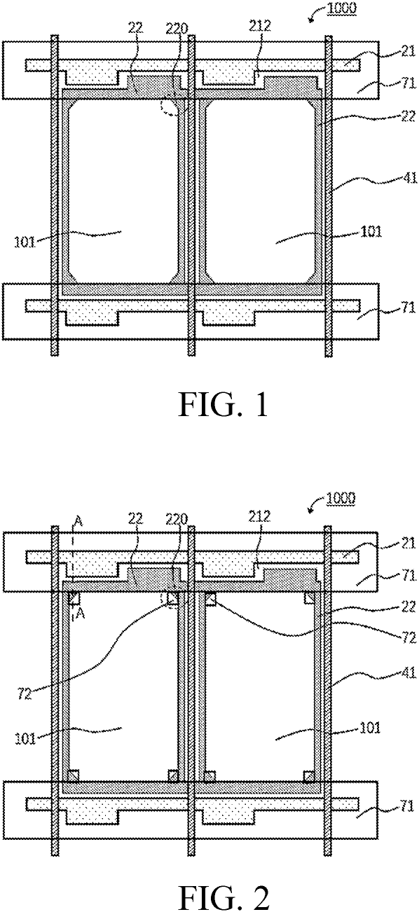

### DETAILED DESCRIPTION OF PREFERRED EMBODIMENTS

The technical solutions in the embodiments of the present application will be clearly and completely described below with reference to the drawings in the embodiments of the present application. Obviously, the embodiments are only a part of the embodiments of the present application, but not all the embodiments. Based on these embodiments of the present application, other embodiments obtained by those skilled in the art without doing creative work fall into the protection scope of the present application.

In the description of this application, it should be understood that the orientations or positional relationships indicated by the terms “center”, “longitudinal”, “transverse”, “length”, “width”, “thickness”, “above”, “below”, “front”, “back”, “left”, “right”, “vertical”, “horizontal”, “top”, “bottom”, “inner”, “outer”, “clockwise”, “counterclockwise” etc., are based on those shown in the drawings. It is only for the convenience of describing the present application and simplifying the description, rather than indicating or implying that the device or element referred to must have a specific orientation, be constructed and operate in a specific orientation, and therefore cannot be construed as a limitation of the present application. In addition, the terms “first” and “second” are used for descriptive purposes only, and cannot be understood as indicating or implying relative importance or implicitly indicating the number of technical features indicated. Thus, the features defined as “first” and “second” may explicitly or implicitly include one or more of the features. In the description of this application, the meaning of “plurality” is two or more, unless otherwise specifically limited.

In the description of this application, it should be noted that, unless otherwise specified and limited, the terms “installation”, “connected”, and “connection” should be understood in a broad sense. For example, it can be fixed or detachable connected, or connected integrally. It can be a mechanical connection, an electrical connection, or can communicate with each other. It can be directly connected or indirectly connected through an intermediate medium. It can be the connection between two elements or the interaction between two elements. Those of ordinary skill in the art can understand the specific meanings of the above terms in this application according to specific situations.

In this application, unless otherwise clearly specified and defined, the first feature “above” or “below” the second feature may include the first feature and the second feature in direct contact, it may also include that the first feature and the second feature are not in direct contact but are in contact through another feature between them. Moreover, the first feature is “higher”, “above” and “on” the second feature includes that the first feature is directly above and obliquely above the second feature, or simply means that the first feature is higher in level than the second feature. The first feature is “lower”, “below” and “under” the second feature includes that the first feature is directly below and obliquely below the second feature, or simply means that the first feature is lower in level than the second feature.

The following disclosure provides various embodiments or examples for implementing various structures of the present application. In order to simplify the disclosure of the present application, the components and settings in specific embodiments are described below. Certainly, they are only embodiments and are not to limit this application. Moreover, the present application may repeat reference numerals and/or reference letters in various embodiments. Such repetition is for simplicity and clarity and does not indicate the relationship between the various embodiments and/or settings discussed. In addition, the present application provides embodiments of various specific processes and materials, but those of ordinary skill in the art may consider the application of other processes and / or the use of other materials.

Please refer to FIG. 2 to FIG. 8. The present application proposes a display panel 1000, including: an array substrate 100 including a plurality of scan lines 21, a plurality of data lines 41, and a first common electrode 22, wherein the plurality of scan lines 21 and the plurality of data lines 41 are intersected to form a plurality of sub-pixel regions 101, and the first common electrode 22 includes a corner portion 220 positioned within a corresponding sub-pixel region 101; and a light-shielding portion 72 covering the corner portion 220.

In this application, through providing a light-shielding portion at a position corresponding to the corner portion of the first common electrode, the corner portion covered with the light-shielding portion relieves the problem of brightness increase in a dark state caused by light reflection from the corner portion of the first common electrode, improves the contrast of the display panel, and improves the display quality.

The technical solution of the present application will be described below with reference to specific embodiments.

### Embodiment 1

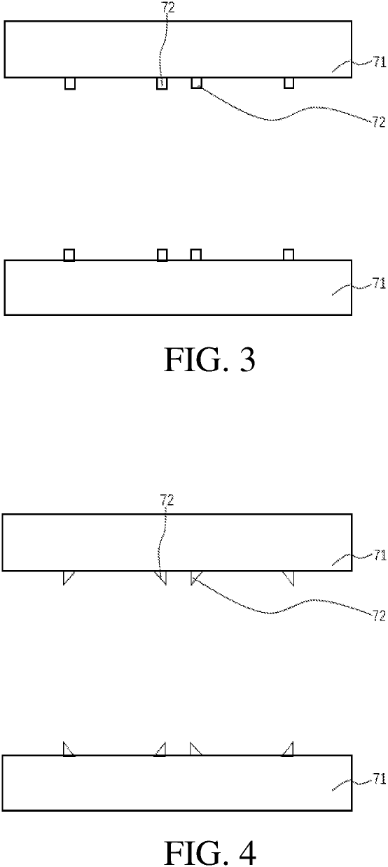

Please refer to FIG. 2, FIG. 3, and FIG. 4. This embodiment proposes a display panel 1000, including an array substrate 100 including a plurality of scan lines 21, a plurality of data lines 41, and a first common electrode 22, wherein the plurality of scan lines 21 and the plurality of data lines 41 are intersected to form a plurality of sub-pixel regions 101, and the first common electrode 22 includes a corner portion 220 positioned within a corresponding sub-pixel region 101; and a light-shielding portion 72 covering the corner portion 220.

Specifically, FIG. 2 illustrates a partial structure of a display panel. The display panel 1000 includes but is not limited to these structures: a scan line 21, a data line 41, a first common electrode 22, a black matrix 71, and a light-shielding portion 72. The scan line 21 and the data line 41 surround to form a plurality of sub-pixels 101, and the black matrix 71 covers the portion of the first common electrode 22 extending in the first direction and the scan line 21. In this application, the first direction is a horizontal direction or a direction in which the scan line extends. The first common electrode 22 is a common electrode (Acom) on the side of the array substrate. The first common electrode has one or more corner portions 220 in the sub-pixel 101, and the corner portion is an intersection portion when the common electrode 22 extends in the first direction and the second direction. The first direction can be perpendicular to the second direction, for example, the first direction is a horizontal direction and the second direction is a vertical direction. However, due to the capability limitation of exposure equipment, the corner portion of the first common electrode cannot be fully exposed during actual production, and the corner portion of the first common electrode will be exposed to the approximate shape of a circular arc, polygon, or triangle. The corner portion 220 is shown in the dashed circle of FIG. 2. In this embodiment, the display panel has a light-shielding portion 72 that covers the corner portion 220. The light-shielding part 72 can shield the light reflection and light leakage that occur at the corner portion 220 of the display panel in a dark state. Therefore, the brightness of the display panel in the dark state is reduced, the contrast of the display panel is improved, and the user’s viewing experience is improved. It should be noted that the light-shielding portion 72 covering the corner portion 220 means that the orthographic projection of the light-shielding portion 72 on the array substrate 100 covers the orthographic projection of the corner portion 220 on the array substrate 100.

Please refer to FIG. 3 and FIG. 4. The shape of the light-shielding portion 72 can be square, triangular, or circular.

Please refer to FIG. 2, FIG. 3, and FIG. 4. In some embodiments, the display panel 1000 further includes a black matrix 71 covering the plurality of scan lines 21. The black matrix 71 is connected to the light-shielding portion 72, i.e. the black matrix 71 and the light-shielding portion 72 are connected to each other. In some embodiments, the black matrix 71 can also cover the data line 41 or only cover the data line 41. It should be noted that when the black matrix 71 covers the scan lines but not the data lines, the shielding electrodes (DBS electrodes) can be covered on the data lines 41 of the array substrate 100 to play a light-shielding role.

Please refer to FIG. 2, FIG. 3, and FIG. 4. In some embodiments, the light-shielding portion 72 can be disposed on the same layer as the black matrix 71. The material of the light-shielding portion 72 is the same as the material of the black matrix 71. For example, the material of the light-shielding portion 72 and the material of the black matrix 71 are both black resin materials.

In this embodiment, the light-shielding portion connected to the black matrix is provided to block the light reflection and light leakage that easily occur when the display panel is in a dark state. Therefore, the contrast of the display panel and the user’s viewing experience are improved.

### Embodiment 2

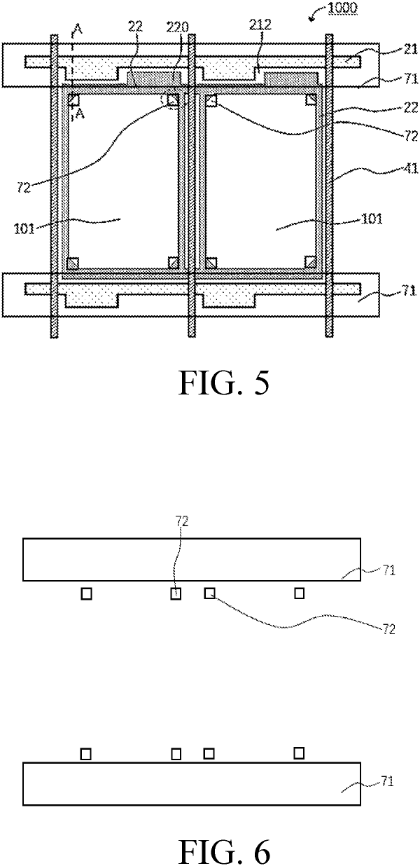

Please refer to FIGS. 5 and 6. This embodiment is the same as or similar to the embodiment 1, and the difference is that the display panel 1000 includes a black matrix 71 covering a plurality of scan lines 21, and the light-shielding portion 72 and the black matrix 71 are not connected to each other.

Specifically, the corner portion 220 is shown in the dotted circle of FIG. 5. In this embodiment, the display panel has a light-shielding portion 72 that covers the corner portion 220. The light-shielding portion 72 can block the light reflection and light leakage that easily occur at the corner portion 220 when the display panel is in a dark state. Therefore, the contrast of the display panel and the user’s viewing experience are improved. It should be noted that the light-shielding portion 72 covering the corner portion 220 means that the orthographic projection of the light-shielding portion 72 on the array substrate 100 covers the orthographic projection of the corner portion 220 on the array substrate 100.

Please refer to FIG. 5 and FIG. 6. In some embodiments, the display panel 1000 includes a black matrix 71 covering a plurality of scan lines 21, the light-shielding portion 72 and the black matrix 71 are not connected to each other, i.e. the black matrix 71 and the light-shielding portion 72 are not in contact connection. For example, FIG. 5 in this embodiment has a narrower black matrix 71 than that in FIG. 2 in the previous embodiment so that the light-shielding portion 72 and the black matrix 71 are not connected to each other. In some embodiments, the black matrix 71 can also cover the data line 41 or cover only the data line 41. It should be noted that when the black matrix 71 covers the scan lines but not the data lines, the shielding electrodes (DBS electrodes) can be covered on the data lines 41 of the array substrate 100 to play a light-shielding role.

Further specifically, the shape of the light-shielding portion 72 can be rectangular, triangular, circular, or the like.

Please refer to FIG. 5 and FIG. 6. In some embodiments, the light-shielding portion 72 can be disposed in the same layer as the black matrix 71 or in a different layer from the black matrix 71. The material of the light-shielding portion 72 is the same as the material of the black matrix 71. For example, the material of the light-shielding portion 72 and the material of the black matrix 71 are both black resin materials.

In this embodiment, through providing a light-shielding portion that is not connected to the black matrix to shield the corner portion, the light-shielding portion can block the light reflection and light leakage that easily occur at the corner portion when the display panel is in a dark state. Therefore, the contrast of the display panel is improved, and the user’s viewing experience is improved.

### Embodiment 3

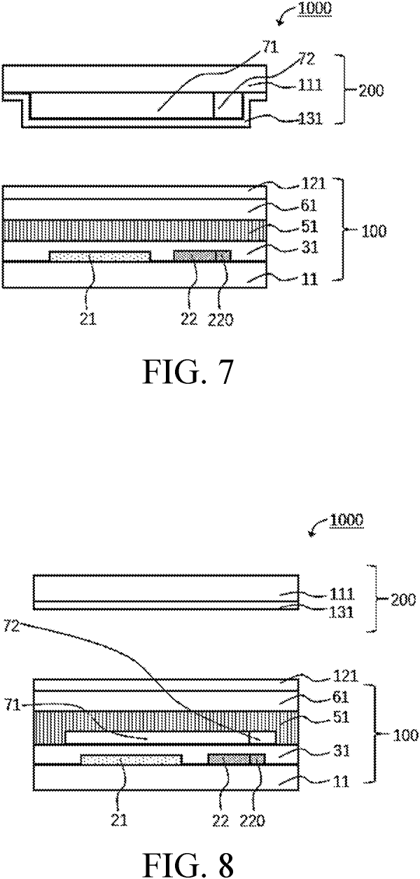

Please refer to FIG. 7, which is a schematic cross-sectional view taken along the AA dotted line in FIGS. 2 and 5 of the above embodiment. Based on the above embodiment, the display panel 1000 further includes a color filter substrate 200, which is disposed opposite to the array substrate 100. The color filter substrate 200 includes a light-shielding portion 72 and a black matrix 71. Specifically, the color filter substrate 200 is disposed opposite to the array substrate 100, and a structure such as a liquid crystal layer is disposed between the color filter substrate 200 and the array substrate 100.

Please refer to FIG. 7. In this embodiment, the array substrate 100 further includes an insulating layer 31, a color resist layer 51, and a pixel electrode layer 121. The insulating layer 31 is disposed on the scan line 21, the color resist layer 51 is disposed on the insulating layer 31, the pixel electrode layer 121 is disposed on the color resist layer 51, and the first common electrode 22 and the scan line 21 are positioned in the same layer and have the same material. The first common electrode 22 and the scan line 21 are positioned in the same layer and have the same material, i.e. the first common electrode 22 and the scan line 21 can be formed by patterning metal through the same process.

Please refer to FIG. 7. In some embodiments, the array substrate 100 includes but is not limited to the insulating layer 31, the color resist layer 51, and the pixel electrode layer 121. The insulating layer 31 can optionally include a gate insulating layer and an insulating protective layer. An active layer (semiconductor layer) can also be disposed on the gate insulating layer, and a source/drain layer metal can also be disposed on the active layer (semiconductor layer), and an insulating protective layer can be disposed on the source/drain layer metal. The color resist layer 51 can be red color resist, green color resist, blue color resist, and other color resist materials in different sub-pixels 101. Another insulating material layer 61 can also be disposed between the pixel electrode layer 121 and the color resist layer 51. The other insulating material layer 61 between the pixel electrode layer 121 and the color resist layer 51 includes, but is not limited to, an organic planarization layer or/and an inorganic insulating layer.

Please refer to FIG. 7. In this embodiment, the color filter substrate 200 can include a second common electrode 131. The second common electrode 131 is disposed on the light-shielding portion 72 and the black matrix 71.

Specifically, please refer to FIG. 7. The color filter substrate 200 includes a base 111, a light-shielding portion 72, a black matrix 71, and a second common electrode 131. The base 111 can be glass, and the light-shielding portion 72 and the black matrix 71 are disposed on a side of the base 111 close to the array substrate 100. The second common electrode 131 is disposed on a side of the light-shielding portion 72 and the black matrix 71 close to the array substrate 100. The function of the second common electrode 131 is to form an electric field with the pixel electrode layer 121 to drive the liquid crystal layer between the color filter substrate 200 and the array substrate 100 to rotate.

Further, specifically, the shape of the light-shielding portion 72 can be rectangular, triangular, circular, or the like.

In some embodiments, the material of the light-shielding portion 72 is the same as the material of the black matrix 71. For example, the material of the light-shielding portion 72 and the material of the black matrix 71 both are black resin materials.

In some embodiments, the light-shielding portion 72 and the black matrix 71 can be connected to each other or not. In this embodiment, through providing a light-shielding portion on the color filter substrate to shield the corner portion, the light-shielding portion can block the light reflection and light leakage that easily occur at the corner portion when the display panel is in a dark state. Therefore, the contrast of the display panel is improved, and the user’s viewing experience is improved.

### Embodiment 4

Please refer to FIG. 8. FIG. 8 shows a schematic diagram of the cross-section view taken along the AA dotted line in FIG. 2 of embodiment 1 and FIG. 5 of embodiment 2. Based on the embodiment 1 and embodiment 2, this embodiment differs from embodiment 3 in that both the light-shielding portion 72 and the black matrix 71 are disposed on the array substrate, i.e. the array substrate 100 includes the light-shielding portion 72 and the black matrix 71.

Please refer to FIG. 8. In this embodiment, the array substrate 100 further includes an insulating layer 31, a color resist layer 51, and a pixel electrode layer 121. The insulating layer 31 is disposed on the scanline 21, and the light-shielding portion 72 and the black matrix 71 are disposed on the insulating layer 31. The color resist layer 51 is disposed on the light-shielding portion 72 and the black matrix 71. The pixel electrode layer 121 is disposed on the color resist layer 51. The first common electrode 22 and the scan line 21 are positioned in the same layer and have the same material. The display panel 1000 further includes a color filter substrate 200, and the color filter substrate 200 includes a second common electrode 131. The first common electrode 22 and the scan line 21 are positioned in the same layer and have the same material, i.e. the first common electrode 22 and the scan line 21 can be formed by patterning metal through the same process.

Specifically, the color filter substrate 200 is disposed opposite to the array substrate 100, and structures such as a liquid crystal layer or the like are disposed between the color filter substrate 200 and the array substrate 100.

Please refer to FIG. 8. In some embodiments, the array substrate 100 includes, but is not limited to, the scan line 21, the first common electrode 22, the insulating layer 31, the light-shielding portion 72, the black matrix 71, the color resist layer 51, and the pixel electrode layer 121. The insulating layer 31 can optionally include a gate insulating layer and an insulating protective layer. An active layer (semiconductor layer) can also be disposed on the gate insulating layer, and a source/drain layer metal can also be disposed on the active layer (semiconductor layer), and an insulating protective layer can be disposed on the source/drain layer metal. The light-shielding portion 72 and the black matrix 71 can be disposed on the insulating layer 31, and the color resist layer 51 is disposed on the light-shielding portion 72 and the black matrix 71. The color resist layer 51 can be red color resist, green color resist, blue color resist, and other color resist materials in different sub-pixels 101. Another insulating material layer 61 can also be disposed between the pixel electrode layer 121 and the color resist layer 51. The other insulating material layer 61 between the pixel electrode layer 121 and the color resist layer 51 includes, but is not limited to, an organic planarization layer or/and an inorganic insulating layer.

Please refer to FIG. 8. In this embodiment, the color filter substrate 200 can include a base 111 and a second common electrode 131. The base 111 can be glass, and the second common electrode 131 is disposed on a side of the base 111 of the color filter substrate 200 close to the array substrate 100. The function of the second common electrode 131 is to form an electric field with the pixel electrode layer 121 to drive the liquid crystal layer between the color filter substrate 200 and the array substrate 100 to rotate.

Further, specifically, the shape of the light-shielding portion 72 can be square, triangular, circular, etc., and is not limited, as long as the light-shielding portion 72 can block the light reflection and light leakage that easily occur at the corner portion 220 when the display panel is in a dark state.

In some embodiments, the material of the light-shielding portion 72 is the same as the material of the black matrix 71. For example, the material of the light-shielding portion 72 and the material of the black matrix 71 are black resin materials.

In some embodiments, the light-shielding portion 72 and the black matrix 71 can be connected to each other or not. In this embodiment, through providing a light-shielding portion on the array substrate to shield the corner portion, the light-shielding portion can block the light reflection and light leakage that easily occur at the corner portion when the display panel is in a dark state, thereby improving the contrast of the display panel and improving the user’s viewing experience.

As described in the above embodiments, although the arrangement of the light-shielding portion 72 on the display panel 1000 is exemplified, it is not limited to the above embodiments. For example, the light-shielding portion 72 and the black matrix 71 can be disposed on the color filter substrate 200. The color filter substrate 200 can include a base 111, a light-shielding portion 72, a black matrix 71, a color resist layer 51, and a second common electrode 131. The structure of the color filter substrate 100 can be that the light-shielding portion 72 and the black matrix 71 are the same layer and are disposed on a side of the base 111 close to the array substrate 100. The color resist layer 51 is disposed on the surface of the light-shielding portion 72 and the black matrix 71 close to the array substrate 100. The second common electrode 131 is disposed on the surface of the color resist layer 51 close to the array substrate 100.

The present application also proposes a display device, wherein the display device includes a backlight module and any one of the above-mentioned display panels on the backlight module. The working principle of the display device in this embodiment is the same as or similar to the working principle of the above-mentioned display panel, which will not be repeated here.

In this application, through providing a light-shielding portion at a position corresponding to a corner portion of the first common electrode, the light-shielding portion covering the corner portion improves brightness increase in a dark state caused by the reflection of light by the corner portion of the first common electrode, improves the contrast of the display panel, and improves the display quality.

In the above embodiments, the description of each embodiment has its own emphasis. For a part that is not detailed in an embodiment, please refer to the related descriptions of other embodiments.

The embodiments of the present application are described in detail above, and specific examples are used in this article to explain the principles and implementation of the present application. The descriptions of the above embodiments are only used to help understand the technical solutions and core ideas of the present application. Those of ordinary skill in the art should understand that they can still modify the technical solutions described in the foregoing embodiments, or equivalently substitute some of the technical features. However, these modifications or substitutions do not deviate the essence of the corresponding technical solutions from the scope of the technical solutions in the embodiments of the present application.

What is claimed is:

1. A display panel, comprising:
an array substrate comprising a plurality of scan lines, a plurality of data lines, and a first common electrode, wherein the plurality of scan lines and the plurality of data lines are intersected to form a plurality of sub-pixel regions, and the first common electrode comprises a corner portion positioned within a corresponding sub-pixel region; and
a light-shielding portion covering the corner portion.

2. The display panel according to claim 1, further comprising a black matrix covering the plurality of scan lines, wherein the black matrix is connected to the light-shielding portion.

3. The display panel according to claim 1, further comprising a black matrix covering the plurality of scan lines, wherein the light-shielding portion and the black matrix are not connected to each other.

4. The display panel according to claim 2, wherein material of the light-shielding portion is same as material of the black matrix.

5. The display panel according to claim 3, wherein material of the light-shielding portion is same as material of the black matrix.

6. The display panel according to claim 2, further comprising a color filter substrate disposed opposite to the array substrate, wherein the color filter substrate comprises the light-shielding portion and the black matrix.

7. The display panel according to claim 3, further comprising a color filter substrate disposed opposite to the array substrate, wherein the color filter substrate comprises the light-shielding portion and the black matrix.

8. The display panel according to claim 2, wherein the array substrate comprises the light-shielding portion and the black matrix.

9. The display panel according to claim 3, wherein the array substrate comprises the light-shielding portion and the black matrix.

10. The display panel according to claim 6, wherein the array substrate further comprises an insulating layer, a color resist layer, and a pixel electrode layer, the insulating layer is disposed on the plurality of scan lines, the color resist layer is disposed on the insulating layer, the pixel electrode layer is disposed on the color resist layer, and the first common electrode and the plurality of scan lines are positioned in same layer and have same material.

11. The display panel according to claim 7, wherein the array substrate further comprises an insulating layer, a color resist layer, and a pixel electrode layer, the insulating layer is disposed on the plurality of scan lines, the color resist layer is disposed on the insulating layer, the pixel electrode layer is disposed on the color resist layer, and the first common electrode and the plurality of scan lines are positioned in same layer and have same material.

12. The display panel according to claim 10, wherein the color filter substrate comprises a second common electrode, and the second common electrode is disposed on the light-shielding portion and the black matrix.

13. The display panel according to claim 11, wherein the color filter substrate comprises a second common electrode, and the second common electrode is disposed on the light-shielding portion and the black matrix.

14. The display panel according to claim 8, wherein the array substrate further comprises an insulating layer, a color resist layer, and a pixel electrode layer, the insulating layer is disposed on the plurality of scan lines, the color resist layer is disposed on the insulating layer, the pixel electrode layer is disposed on the color resist layer, and the first common electrode and the plurality of scan lines are positioned in same layer and have same material; and
wherein the display panel further comprises a color filter substrate, and the color filter substrate comprises a second common electrode.

15. The display panel according to claim 9, wherein the array substrate further comprises an insulating layer, a color resist layer, and a pixel electrode layer, the insulating layer is disposed on the plurality of scan lines, the color resist layer is disposed on the insulating layer, the pixel electrode layer is disposed on the color resist layer, and the first common electrode and the plurality of scan lines are positioned in same layer and have same material; and
wherein the display panel further comprises a color filter substrate, and the color filter substrate comprises a second common electrode.

16. A display device, comprising a backlight module and a display panel positioned on the backlight module, wherein the display panel comprises:
an array substrate comprising a plurality of scan lines, a plurality of data lines, and a first common electrode, wherein the plurality of scan lines and the plurality of data lines are intersected to form a plurality of sub-pixel regions, and the first common electrode comprises a corner portion positioned within a corresponding sub-pixel region; and
a light-shielding portion covering the corner portion.

17. The display device according to claim 16, further comprising a black matrix covering the plurality of scan lines, wherein the black matrix is connected to the light-shielding portion.

18. The display device according to claim 16, further comprising a black matrix covering the plurality of scan lines, wherein the light-shielding portion and the black matrix are not connected to each other.

19. The display device according to claim 17, further comprising a color filter substrate disposed opposite to the array substrate, wherein the color filter substrate comprises the light-shielding portion and the black matrix.

20. The display device according to claim 17, wherein the array substrate comprises the light-shielding portion and the black matrix.
